(19) United States
(12) Patent Application Publication
(10) Pub. No.: US 2025/0255160 A1
(43) Pub. Date: Aug. 7, 2025

(54) DISPLAY DEVICE

(71) Applicant: Samsung Display Co., Ltd., Yongin-si (KR)

(72) Inventors: Gak Seok LEE, Yongin-si (KR); Keun Chan OH, Yongin-si (KR); DO-HYUK KWON, Yongin-si (KR); Byung-Chul KIM, Yongin-si (KR); Han Joon YOO, Yongin-si (KR); Kyung Hwan JEON, Yongin-si (KR)

(73) Assignee: Samsung Display Co., Ltd., Yongin-si (KR)

(21) Appl. No.: 18/888,991

(22) Filed: Sep. 18, 2024

(30) Foreign Application Priority Data
Feb. 2, 2024 (KR) 10-2024-0016803

(51) Int. Cl. H10K 59/80; H10K 59/38

(52) U.S. Cl. CPC H10K 59/8792; H10K 59/38

(57) ABSTRACT

A display device includes a first substrate, a transistor, a light emitting diode, an encapsulation layer, a color mixing prevention layer, a partition wall, a first color conversion layer, a second color conversion layer, and a transmission layer. The transistor is disposed on a surface of the first substrate. The light emitting diode is electrically connected to the transistor. The encapsulation layer is disposed on the light emitting diode. The color mixing prevention layer is disposed on the encapsulation layer. The partition wall is disposed on the color mixing prevention layer and includes a first opening, a second opening, and a third opening. The first color conversion layer is disposed in the first opening. The second color conversion layer is disposed in the second opening. The transmission layer is disposed in the third opening. The color mixing prevention layer includes one or more dichroic dyes.

### CROSS-REFERENCE TO RELATED APPLICATION(S)

This U.S. non-provisional patent application claims priority to and the benefits of Korean Patent Application No. 10-2024-0016803 under 35 U.S.C. § 119, filed in the Korean Intellectual Property Office on Feb. 2, 2024, the entire contents of which are hereby incorporated by reference.

### BACKGROUND

### 1. Technical Field

The disclosure generally relates to a display device.

### 2. Description of the Related Art

In a conventional light emitting element, holes supplied from an anode and electrons supplied from a cathode may combine in a light-emitting layer disposed between the anode and the cathode to form an exciton. In a case that the exciton is stabilized, it emits light.

Light emitting diodes have various advantages, such as relatively wide viewing angle, relatively fast response speed, relative thinness, and relatively low power consumption. As such, light emitting diodes are widely applied to (or used in association with) various electrical and electronic devices, such as televisions, monitors, mobile phones, etc.

A display device including a color conversion layer has been proposed to implement a relatively highly efficient display device. The color conversion layer of the display device may convert incident light into a different color.

The background provided herein is for the purpose of generally presenting the context of the disclosure. Work of the presently named inventors, to the extent that it is described in this background section, as well as aspects of the description that may not otherwise qualify as prior art at the time of filing, are neither expressly nor impliedly admitted as prior art against the disclosure.

### SUMMARY

Some aspects are capable of providing an improved color gamut in a display device (such as a high-resolution display device).

Additional aspects will be set forth in the detailed description, which follows, and in part, will be apparent from the disclosure, or may be learned by practice of the disclosed embodiments and/or the claimed subject matter.

According to some embodiments, a display device includes a first substrate, a transistor, a light emitting diode, an encapsulation layer, a color mixing prevention layer, a partition wall, a first color conversion layer, a second color conversion layer, and a transmission layer. The transistor is disposed on a surface of the first substrate. The light emitting element is electrically connected to the transistor. The encapsulation layer is disposed on the light emitting diode. The color mixing prevention layer is disposed on the encapsulation layer. The partition wall is disposed on the color mixing prevention layer and includes a first opening, a second opening, and a third opening. The first color conversion layer is disposed in the first opening. The second color conversion layer is disposed in the second opening. The transmission layer is disposed in the third opening. The color mixing prevention layer includes one or more dichroic dyes.

In some embodiments, the one or more dichroic dyes may have a major axis along which light is transmitted and a minor axis along which light is absorbed. The major axis may extend in a first direction perpendicular to the surface.

In some embodiments, the minor axis may extend in a second direction perpendicular to the first direction.

In some embodiments, the one or more dichroic dyes may include at least one of a red dichroic dye, a green dichroic dye, and a blue dichroic dye.

In some embodiments, the color mixing prevention layer may be configured to absorb light having an oblique angle of incidence with the color mixing prevention layer.

In some embodiments, the partition wall, the first color conversion layer, the second color conversion layer, and the transmission layer may have respective first surfaces facing the first substrate. The respective first surfaces of the partition wall, the first color conversion layer, the second color conversion layer, and the transmission layer may directly contact the color mixing prevention layer.

In some embodiments, in a view in a direction perpendicular to the surface, the color mixing prevention layer may respectively overlap each of the first opening, the second opening, and the third opening, and may not overlap at least a portion of the partition wall.

In some embodiments, in a view in a direction perpendicular to the surface, the color mixing prevention layer may overlap at least one of the first color conversion layer, the second color conversion layer, and the transmission layer.

In some embodiments, in the view, the color mixing prevention layer may be spaced apart from at least one of the first color conversion layer, the second color conversion layer, and the transmission layer.

According to some embodiments, a display device includes a first substrate, a transistor, a light emitting diode, an encapsulation layer, a color mixing prevention layer, a second substrate, a partition wall, a first color conversion layer, a second color conversion layer, and a third color conversion layer. The transistor is disposed on a surface of the first substrate. The light emitting diode is electrically connected to the transistor. The encapsulation layer is disposed on the light emitting diode. The color mixing prevention layer is disposed on the encapsulation layer. The second substrate overlaps the first substrate in a direction perpendicular to the surface. The partition wall is disposed on the second substrate and includes a first opening, a second opening, and a third opening. The first color conversion layer is disposed in the first opening. The second color conversion layer is disposed in the second opening. The transmission layer is disposed in the third opening. The color mixing prevention layer includes one or more dichroic dyes.

In some embodiments, the display device may further include a filling layer disposed between the partition wall and the encapsulation layer in the direction.

In some embodiments, the color mixing prevention layer may be disposed between the filling layer and the encapsulation layer in the direction.

In some embodiments, the color mixing prevention layer may overlap an entirety of the surface in the direction.

In some embodiments, the color mixing prevention layer may respectively overlap each of the first color conversion layer, the second color conversion layer, and the transmission layer in a view in the direction.

In some embodiments, the color mixing prevention layer may not overlap at least a portion of the partition wall in the view.

In some embodiments, the color mixing prevention layer may overlap at least one of the first color conversion layer, the second color conversion layer, and the transmission layer in a view in the direction.

In some embodiments, the color mixing prevention layer may not overlap at least one of the first color conversion layer, the second color conversion layer, and the transmission layer in the view.

In some embodiments, the color mixing prevention layer may be disposed between the filling layer and the partition wall in the direction.

In some embodiments, the color mixing prevention layer may respectively overlap each of the first opening, the second opening, and the third opening in a view in the direction. In the view, the color mixing prevention layer may be spaced apart from at least a portion of a surface of the partition wall.

In some embodiments, the color mixing prevention layer may not overlap at least one of the first color conversion layer, the second color conversion layer, and the transmission layer in a view in the direction.

According to various embodiments, color mixing can be prevented (or at least mitigated) in a display device (such as a high-resolution display device), and color reproduction can be improved by improving color purity.

The foregoing general description and the following detailed description are illustrative and explanatory and are intended to provide further explanation of the claimed subject matter.

### BRIEF DESCRIPTION OF THE DRAWINGS

Various embodiments disclosed herein are illustrated by way of example, and not by way of limitation, in the figures of the accompanying drawings, in which like reference numerals and/or characters refer to similar elements.

FIG. 1 is a schematic exploded perspective view of a display device according to an embodiment.

FIG. 2 is a schematic cross-sectional view of a display panel according to an embodiment.

FIG. 3 is a schematic plan view of a portion of a pixel of a display panel according to an embodiment.

FIG. 4 is a schematic cross-sectional view of a display panel according to an embodiment.

FIG. 5 is an enlarged schematic cross-sectional view of a partial area of the display panel depicted in FIG. 4 according to an embodiment.

FIG. 6 is a schematic diagram of an arrangement of a dichroic dye according to an embodiment.

FIG. 7 is a graph showing the transmittance by wavelength of a color mixing prevention layer containing a dichroic dye according to an embodiment.

FIGS. 8, 9, 10, 11, 12, 13, 14, and 15 are cross-sectional views of a display panel according to various embodiments.

### DETAILED DESCRIPTION OF THE EMBODIMENTS

In the following description, for the purposes of explanation, numerous specific details are set forth to provide a thorough understanding of various embodiments or implementations. The terms “embodiments” and “implementations” may be used interchangeably to describe one or more non-limiting examples of systems, apparatuses, methods, etc., described herein. It is apparent, however, that various embodiments may be practiced without these specific details or with one or more equivalent arrangements. In other instances, well-known structures and devices are shown in block diagram form to avoid unnecessarily obscuring various embodiments. Further, various embodiments may be different, but do not have to be exclusive. For example, specific shapes, configurations, and characteristics of an embodiment may be used or implemented in another embodiment without departing from the teachings of the disclosure.

Unless otherwise specified, the illustrated embodiments are to be understood as providing example features of varying detail of some embodiments. Thus, unless otherwise specified, the features, components, modules, layers, films, regions, aspects, structures, etc. (hereinafter individually or collectively referred to as an “element” or “elements”), of the various illustrations may be otherwise combined, separated, interchanged, and/or rearranged without departing from the teachings of the disclosure.

The use of cross-hatching and/or shading in the accompanying drawings is generally provided to clarify boundaries between adjacent elements. As such, neither the presence nor the absence of cross-hatching or shading is intended to convey or indicate any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. As such, the sizes and relative sizes of the respective elements are not necessarily limited to the sizes and relative sizes shown in the drawings. When an embodiment may be implemented differently, a specific process order may be performed differently from the described order. For example, two consecutively described processes may be performed substantially at the same time or performed in an order opposite the described order. Also, like reference numerals and/or reference characters denote like elements.

When an element, such as a layer, is referred to as being “on,” “over,” “connected to (or with),” or “coupled to (or with)” another element, it may be directly on, directly over, directly connected to (or with), or directly coupled to (or with) the other element or at least one intervening element may be present. When, however, an element is referred to as being “directly on,” “directly over,” “directly connected to (or with),” or “directly coupled to (or with)” another element, there are no intervening elements present. Other terms and/or phrases, if used herein, to describe a relationship between elements should be interpreted in a like fashion, such as “between” versus “directly between,” “adjacent” versus “directly adjacent,” “on” versus “directly on,” “contacting” versus “directly contacting,” “touching” versus “directly touching,” etc. Further, the term “connected” may refer to physical, electrical, and/or fluid connection. To this end, for the purposes of this disclosure, the phrase “fluidically connected” may be used with respect to volumes, plenums, holes, openings, etc., that may be connected to one another, either directly or via one or more intervening components or volumes, to form a fluidic connection, similar to how the phrase “electrically connected” is used with respect to components that are connected to form an electric connection.

For the purposes of this disclosure, a first axis extending along a first direction DR1, a second axis extending along a second direction DR2, and a third axis extending along a third direction DR3 are not limited to three axes of a rectangular coordinate system, such as x, y, and z axes of a Cartesian coordinate system, and may be interpreted in a broader sense. For example, the first axis, the second axis, and the third axis may be perpendicular to one another, or may represent different directions that are not perpendicular to one another. Further, if used herein, the phrases “at least one of X, Y, . . . , and Z” and “at least one selected from the group consisting of X, Y, . . . , and Z” may be construed as X only, Y only, . . . , Z only, or any combination of two or more of X, Y, . . . , and Z, such as, for instance, XYZ, XYY, YZ, and ZZ. Also, if used herein, the term “and/or” includes any and all combinations of one or more of the associated listed items.

Although the terms “first,” “second,” “third,” etc., may be used herein to describe various elements, these elements should not be limited by these terms. These terms are used to distinguish one element from another element. Thus, a first element discussed below could be termed a second element without departing from the teachings of the disclosure. To this end, use of such identifiers, e.g., “a first element,” should not be read as suggesting, implicitly or inherently, that there is necessarily another instance, e.g., “a second element.”

Spatially relative terms, such as “beneath,” “below,” “under,” “lower,” “above,” “upper,” “over,” “higher,” “side” (e.g., as in “sidewall”), and the like, may be used herein for descriptive purposes, and thereby, to describe one element's spatial relationship to at least one other element as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” or “over” the other elements or features. Thus, the term “below” can encompass both an orientation of above and below. Furthermore, the apparatus may be otherwise oriented (e.g., rotated 90 degrees or at other orientations), and as such, the spatially relative descriptors used herein interpreted accordingly.

The terminology used herein is for the purpose of describing some embodiments and is not intended to be limiting. As used herein, the singular forms, “a,” “an,” and “the” are intended to include the plural forms as well, unless the context clearly indicates otherwise. It is to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in and of itself, as necessarily encompassing a plurality of items—it is to be understood that a set or a subset can encompass only one member or multiple members (unless the context indicates otherwise).

The terms “comprises,” “comprising,” “includes,” “including,” “has,” “have,” and/or “having” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” “approximately,” and other similar terms, are used as terms of approximation and not as terms of degree, and as such, are utilized to account for inherent deviations in measured, calculated, and/or provided values that would be recognized by one of ordinary skill in the art. Accordingly, the term “substantially,” if used herein, and unless otherwise specified, may mean within 5% of a referenced value. For example, substantially perpendicular may mean within +5% of being parallel. Moreover, the term “between,” if used herein in association with a range of values, is to be understood, unless otherwise indicated, as being inclusive of the start and end values of the range. For example, between 1 and 5 is to be understood as being inclusive of the numbers 1, 2, 3, 4, and 5, not just the numbers 2, 3, and 4.

Various embodiments are described herein with reference to sectional views, isometric views, perspective views, orthographic views, and/or exploded illustrations that are schematic depictions of idealized embodiments and/or intermediate structures. As such, variations from the shapes of the illustrations because of, for example, manufacturing techniques and/or tolerances, are to be expected. Thus, embodiments disclosed herein should not be construed as limited to the particular illustrated shapes of regions, but are to include deviations in shapes that result from, for instance, manufacturing. To this end, regions illustrated in the drawings may be schematic in nature and shapes of these regions may not reflect the actual shapes of regions of a device, and as such, are not intended to be limiting.

As customary in the field, some embodiments may be described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and are not to be interpreted in an idealized or overly formal sense, unless expressly so defined herein.

Hereinafter, various embodiments will be described with reference to the accompanying drawings.

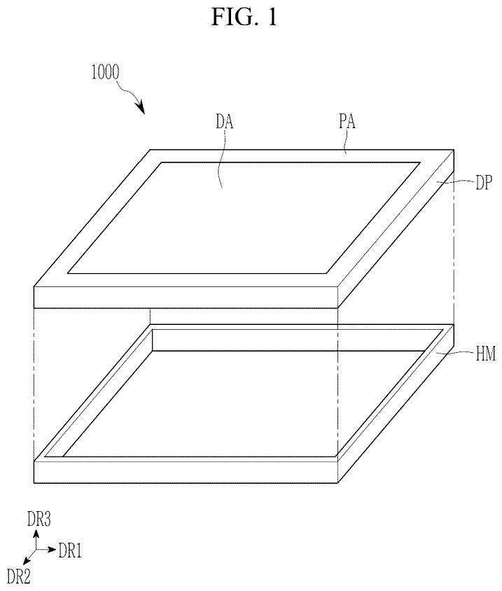

FIG. 1 is a schematic exploded perspective view of a display device according to an embodiment.

Referring to FIG. 1, a display device 1000 according to an embodiment may include a display panel DP and a housing HM.

A side of the display panel DP on (or through) which the image may be displayed may be parallel (or substantially parallel) to a side (or an imaginary plane) defined by the first direction DR1 and the second direction DR2.

The third direction DR3 may indicate the normal direction of a side on which the image may be displayed. For instance, the third direction DR3 may be a thickness direction of the display panel DP.

The front (or upper) and back (or lower) surfaces of each member may be separated by (or spaced apart from one another in) the third direction DR3.

However, the directions indicated by the first to third directions DR1, DR2, DR3 are relative concepts and may be converted to (or representative of) other directions.

The display panel DP may be a flat rigid display panel, but embodiments are limited to such display devices. For instance, the display panel DP may be a flexible display panel, a hybrid display panel including at least one flat rigid portion and at least one flexible portion, and/or any other suitable display panel.

The display panel DP may be (or include) an organic light emitting display panel.

However, the type of display panel DP is not limited to this example. For instance, the display panel DP may be any suitable type of display panel.

For example, the display panel DP may be a liquid crystal display panel, an electrophoretic display panel, an electrowetting display panel, etc.

In some implementations, the display panel DP may be a micro light emitting diode (LED) display panel, a quantum dot LED display panel, a quantum dot organic light emitting diode (OLED) display panel, or the like.

Micro LED display panels typically include light emitting diodes having a size in a range of about 10 to about 100 micrometers to form each pixel.

These micro light emitting diode display panels have at least the following advantages: they use inorganic materials, a backlight can be omitted, a response speed is relatively fast, relatively high brightness can be achieved with relatively low power, and they do not break in a case that they are bent or otherwise flexed.

Quantum dot light emitting diode display panels are typically made by attaching a film containing quantum dots or forming them with a material containing quantum dots.

Quantum dots are particles made of inorganic materials, such as indium, cadmium, etc., that emit light on their own, and have a diameter in a range of several nanometers or less.

By controlling the particle size of the quantum dots, light of a desired color can be emitted (or displayed).

A quantum dot organic light emitting diode display panel is typically made using blue organic light emitting diodes as light sources, and attaching a film containing, for instance, red and green quantum dots respectively over the blue organic light emitting diodes correspondingly associated with red and green pixels, or depositing a material containing, for example, red and green quantum dots in respective regions of at least one layer overlapping the blue organic light emitting diodes correspondingly associated with red and green pixels in, for example, the third direction DR3. In this manner, pixels configured to display different colors (e.g., red, green, and blue colors) may be realized.

It, however, is contemplated that the display panel DP, according to some embodiments, may be made of various other display panels.

As shown in FIG. 1, the display panel DP includes a display area DA where an image may be displayed, and a non-display area PA adjacent to the display area DA.

The non-display area PA may be an area where images are not displayed.

For example, the display area DA may have a square shape, and the non-display area PA may have a shape surrounding the display area DA.

However, the respective shapes and arrangement of the display area DA and the non-display area PA may be relatively designed without being limited to these examples.

The housing HM may provide a determined internal space (or cavity).

The display panel DP may be mounted at least partially inside the housing HM.

In addition to the display panel DP, various electronic components, such as a power supply, a storage device, an audio input/output module, etc., may be mounted (or supported) at least partially inside the housing HM.

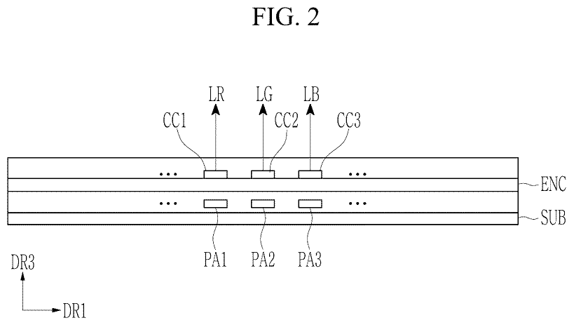

Hereinafter, the display area of the display panel according to an embodiment will be described with reference to FIG. 2.

FIG. 2 is a schematic cross-sectional view of a display panel according to an embodiment.

Referring to FIG. 2, multiple pixels (e.g., first pixel PA1, second pixel PA2, and third pixel PA3) may be disposed on a substrate SUB overlapping the display area DA described in association with FIG. 1 in, for example, the third direction DR3. For descriptive convenience, the pixels may be individually referenced as first pixel PA1, second pixel PA2, and third pixel PA3, or collectively referred to as pixels PA1, PA2, and PA3.

Each of the pixels PA1, PA2, and PA3 may include one or more (e.g., multiple) transistors and at least one light emitting diode connected to at least one of the one or more transistors.

The shape and arrangement of the pixels PA1, PA2, and PA3 may be modified in various ways.

An encapsulation layer ENC may be disposed on the pixels PA1, PA2, and PA3.

The display area DA may be protected from external air, moisture, debris, etc., by the encapsulation layer ENC.

The encapsulation layer ENC may overlap an entire surface of the display area DA in, for example, the third direction DR3, and may be partially disposed on (or in) the non-display area PA.

A first color conversion portion CC1, a second color conversion portion CC2, and a transmission portion CC3 may be disposed on the encapsulation layer ENC.

The first color conversion portion CC1 may overlap the first pixel PA1 in, for instance, the third direction DR3, the second color conversion portion CC2 may overlap the second pixel PA2 in, for instance, the third direction DR3, and the transmission portion CC3 may overlap the third pixel PA3 in, for instance, the third direction DR3.

Light emitted from the first pixel PA1 may pass through the first color conversion portion CC1 to provide red light LR.

Light emitted from the second pixel PA2 may pass through the second color conversion portion CC2 to provide green light LG.

Light emitted from the third pixel PA3 may pass through the transmission portion CC3 to provide blue light LB.

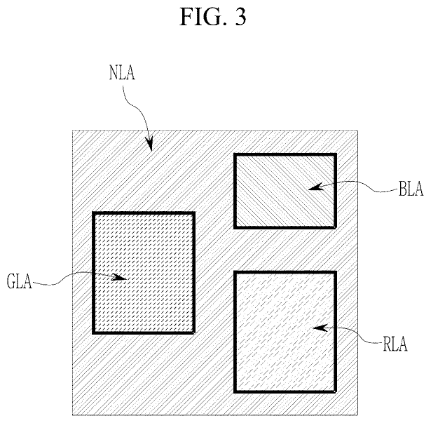

Hereinafter, a display panel according to an embodiment will be described in more detail with reference to FIGS. 3 to 7.

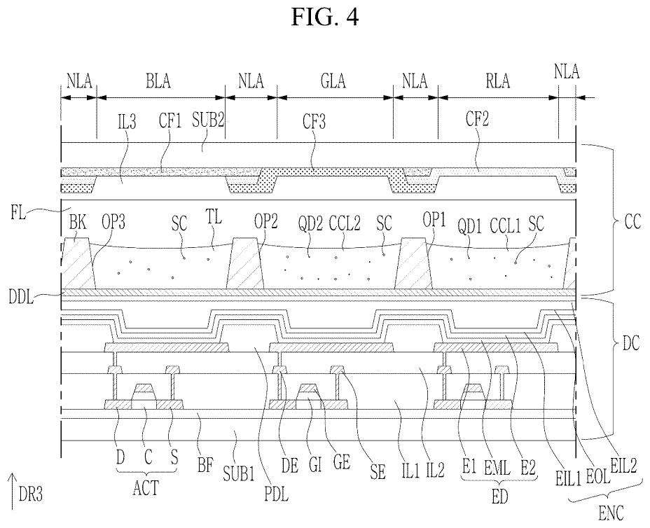

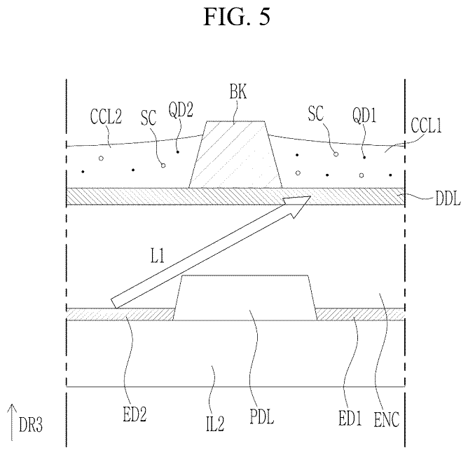

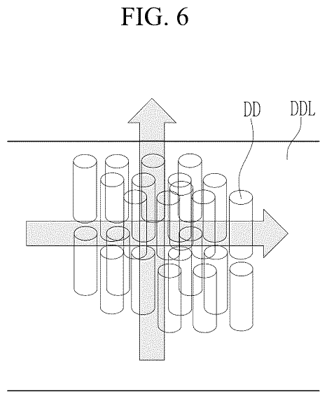

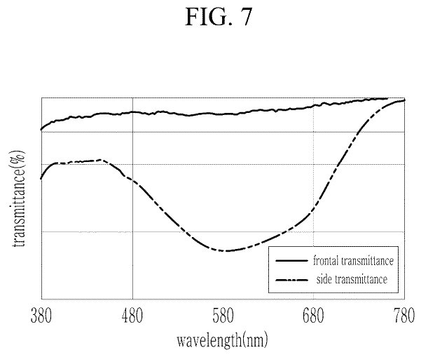

FIG. 3 is a schematic plan view of a portion of a pixel of a display panel according to an embodiment. FIG. 4 is a schematic cross-sectional view of a display panel according to an embodiment. FIG. 5 is an enlarged schematic cross-sectional view of a partial area of the display panel depicted in FIG. 4 according to an embodiment. FIG. 6 is a schematic diagram of an arrangement of a dichroic dye according to an embodiment. FIG. 7 is a graph showing the transmittance by wavelength of a color mixing prevention layer containing a dichroic dye according to an embodiment.

First, referring to FIG. 3, the display area DA described in association with FIG. 1 according to an embodiment includes a red light emitting area RLA, a green light emitting area GLA, and a blue light emitting area BLA.

A non-light emitting area NLA may be disposed between the red light emitting area RLA, the green light emitting area GLA, and the blue light emitting area BLA. For instance, the non-light emitting area NLA may be disposed outside the red light emitting area RLA, the green light emitting area GLA, and the blue light emitting area BLA, and may at least partially surround the red light emitting area RLA, the green light emitting area GLA, and the blue light emitting area BLA.

Each light emitting area may correspond to a pixel.

For example, the blue light emitting area BLA, the red light emitting area RLA, and the green light emitting area GLA may correspond to a blue pixel, a red pixel, and a green pixel, respectively.

Although the red light emitting area RLA, the green light emitting area GLA, and the blue light emitting area BLA are shown having respective rectangular shapes, embodiments are not limited to rectangular shapes. For instance, the shape of the red light emitting area RLA, the green light emitting area GLA, and/or the blue light emitting area BLA may be modified in various ways, e.g., at least one of the red light emitting area RLA, the green light emitting area GLA, and the blue light emitting area BLA may have a circular shape, an oval shape, an elliptical shape, a triangular shape, a pentagonal shape, etc., or may have a free-from shape. Further, the arrangement of the red light emitting area RLA, the green light emitting area GLA, and the blue light emitting area BLA may be modified in various ways.

Hereinafter, an example cross-sectional structure of the display panel DP will be described with reference to FIG. 4.

A display portion DC according to an embodiment may include a first substrate SUB1.

The first substrate SUB1 may include a flexible material, such as plastic, that can be intentionally bent, folded, rolled, twisted, and/or otherwise flexed, as opposed to a conventional rigid substrate. In some embodiments, the first substrate SUB1 may include at least one flexible area and at least one rigid area. In an embodiment, the first substrate SUB1 may be a rigid substrate.

A buffer layer BF may be disposed on the first substrate SUB1.

Depending on the embodiment, the buffer layer BF may be omitted.

The buffer layer BF may include, for instance, silicon nitride (SiNx), silicon dioxide (SiO2), silicon oxynitride, etc.

The buffer layer BF may be disposed between the first substrate SUB1 and a semiconductor layer ACT, and may improve the properties of polycrystalline silicon by blocking impurities from the first substrate SUB1 during a crystallization process to form polycrystalline silicon, and by flattening (or increasing a planarity of) the first substrate SUB1. It is also noted that the buffer layer BF can alleviate stress applied to the semiconductor layer ACT formed on the buffer layer BF.

The semiconductor layer ACT may be disposed on the buffer layer BF.

The semiconductor layer ACT may be made of polycrystalline silicon, an oxide semiconductor, or any other suitable semiconductor material.

The semiconductor layer ACT may include a channel region C, a source region S, and a drain region D.

The source region S and the drain region D may be respectively arranged on opposing sides (e.g., opposing lateral sides) of the channel region C.

The channel region C may be an intrinsic semiconductor that is not doped with impurities, and both the source region S and the drain region D may be extrinsic (or impurity) semiconductors that are doped with conductive impurities.

The semiconductor layer ACT may be made of an oxide semiconductor, in which case a separate protective layer (not shown) may be added to protect the oxide semiconductor material, which may be vulnerable to external environments, such as relatively high temperature environments.

A gate insulating layer GI may be disposed on the semiconductor layer ACT.

The gate insulating layer GI may be formed as a single layer or as a multilayer formation containing at least one of a silicon nitride (SiNx), silicon dioxide (SiO₂), and silicon oxynitride, but embodiments are not limited to these materials.

A gate electrode GE may be disposed on the gate insulating layer GI. The gate electrode GE may include at least one of copper (Cu), a copper alloy, aluminum (Al), an aluminum alloy, molybdenum (Mo), and a molybdenum alloy, but embodiments are not limited to these materials. In some implementations, the gate electrode GE may have a multilayer structure in which at least two metal layers are stacked on each other in, for example, the third direction DR3.

An interlayer insulating layer IL1 may be disposed on both the gate electrode GE and the gate insulating layer GI.

The interlayer insulating layer IL1 may include at least one of silicon nitride (SiNx), silicon dioxide (SiO₂), and silicon oxynitride, but embodiments are not limited to these materials.

Openings exposing the source region S and drain region D may be disposed (or formed) in the interlayer insulating layer IL1.

A source electrode SE and a drain electrode DE may be disposed on the interlayer insulating layer IL1.

The source electrode SE and the drain electrode DE may be respectively connected to the source region S and the drain region D of the semiconductor layer ACT through the openings formed in the interlayer insulating layer IL1.

A protective layer IL2 may be disposed on each of the interlayer insulating layer IL1, the source electrode SE, and the drain electrode DE.

The protective layer IL2 may at least partially cover and flatten a surface overlapping an underlying formation in, for example, the third direction DR3 of, for instance, the interlayer insulating layer IL1, the source electrode SE, and the drain electrode DE. Increasing the planarity of the underlying formation may allow the first electrode E1 to be formed on the protective layer IL2 without (or substantially without) any steps.

The protective layer IL2 may be made of an organic material, such as at least one of a polyacrylate resin and a polyimide resin, and/or a laminated (or multilayer) film of an organic material and an inorganic material.

The first electrode E1 may be disposed on the protective layer IL2.

The first electrode E1 may be electrically connected to the drain electrode DE through an opening in the protective layer IL2.

A driving transistor including, for instance, a gate electrode GE, a semiconductor layer ACT, a source electrode SE, and a drain electrode DE may be connected to the first electrode E1 to supply a driving current to a light emitting diode ED.

In addition to the driving transistor shown in FIG. 4, the display device according to some embodiments may include a switching transistor (not shown) connected to a data line and configured to transmit a data voltage in response to receiving a scan signal, and a switching transistor (not shown) connected to the driving transistor and driven in response to the scan signal. The display device may further include a compensation transistor (not shown) configured to compensate for a threshold voltage of a transistor, such as the driving transistor.

A pixel defining layer PDL may be positioned on the protective layer IL2 and the first electrode E1. The pixel defining layer PDL may have a pixel opening that overlaps the first electrode E1 in, for example, the third direction DR3 and defines (e.g., at least partially bounds) a light emitting area.

The pixel defining layer PDL may contain an organic material, such as at least one of a polyacrylate resin, and a polyimide resin, and/or a silica-based inorganic material.

The pixel opening may, in a view in the third direction DR3, have a planar shape substantially similar to the shape of the first electrode E1 in the view in the third direction DR3. In some implementations, the pixel opening may have a diamond or octagonal shape similar to a diamond in a plan view (e.g., in a view in the third direction DR3), but the shape of the pixel opening is not limited to these examples. For instance, the pixel opening may have any shape in a view in, for instance, the third direction DR3, such as a square shape or other polygonal shape, or may have a circular shape, an oval shape, an elliptical shape, or a free-form shape.

A light emitting layer EML may be disposed on the first electrode E1 and overlap the pixel opening in, for example, the third direction DR3.

The light emitting layer EML may be made of a relatively low-molecular organic material and/or a relatively high-molecular organic material, such as PEDOT (poly(3,4-ethylenedioxythiophene)).

The light emitting layer EML may include a hole injection layer (“HIL”), a hole transporting layer (“HTL”), an electron transporting layer (“ETL”), and an electron injection layer (“EIL”). In some implementations, the light emitting layer EML may be a multilayer structure containing two or more layers.

The light emitting layer EML may be disposed at least partially (e.g., mostly) in the pixel opening, and may be disposed on a side (e.g., a lateral side) of the pixel defining layer PDL.

Although the light emitting layer EML is depicted as overlapping an entire (or substantially entire) surface of the first substrate SUB1, embodiments are not limited to this example. For instance, in some embodiments, the light emitting layer EML may be disposed only in the pixel opening of the pixel defining layer PDL.

A second electrode E2 may be disposed on the light emitting layer EML.

The second electrode E2 may be disposed across (and, thereby, overlap in, for instance, the third direction DR3) multiple pixels and may receive a common voltage through a common voltage transmitter (not shown) in the non-display area PA.

The first electrode E1, the light emitting layer EML, and the second electrode E2 may form a light emitting diode ED.

The first electrode E1 may be an anode, which may be a hole injection electrode, and the second electrode E2 may be a cathode, which may be an electron injection electrode.

However, embodiments are not limited to this example. For instance, the first electrode E1 may be a cathode and the second electrode E2 may be an anode depending on the driving method of the organic light emitting display device.

Holes and electrons may be injected into the light emitting layer EML from the first electrode E1 and the second electrode E2, respectively, and light emission may occur in a case that an exciton (which is a combination of an injected hole and electron) falls from an excited state to a ground state.

The light emitting diode ED according to an embodiment may include multiple light emitting units (or structures). Each light emitting unit may include a light emitting layer. For instance, the light emitting diode ED according to an embodiment may include multiple light emitting layers. The light emitting diode ED may be a tandem structure light emitting diode, e.g., a structure in which multiple light emitting diodes are stacked on one another in, for example, the third direction DR3.

The multiple light emitting layers may emit a same light or different light from one another. As an example, the light emitting diode ED may emit light that is a mixture of green light and blue light. In some implementations, the light emitting diode ED may emit blue light.

An encapsulation layer ENC may be positioned on the second electrode E2. The encapsulation layer ENC may seal the display portion DC by covering not only a top surface of the display portion DC, but also side surfaces of the display portion DC including the light emitting diode ED. Since the light emitting diode ED may be relatively vulnerable (or sensitive) to the permeation of, for instance, moisture and oxygen, the encapsulation layer ENC may seal the display portion DC and block the inflow of external moisture and oxygen to, for instance, the light emitting diode ED.

The encapsulation layer ENC may include multiple layers, and among the multiple layers, the encapsulation layer ENC may be formed as a composite layer that includes both inorganic and organic layers. In some implementations, the encapsulation layer ENC may be formed as a triple layer including a sequential formation of a first inorganic layer EIL1, an organic layer EOL, and a second inorganic layer EIL2, but embodiments are not limited to this example structure.

A color conversion portion CC may be disposed on the encapsulation layer ENC.

The color conversion portion CC may include a color mixing prevention layer DDL disposed on the encapsulation layer ENC. The color mixing prevention layer DDL may overlap an entire (or substantially entire) surface of the first substrate SUB1 in, for example, the third direction DR3. The color mixing prevention layer DDL according to an embodiment may include one or more (e.g., multiple) dichroic dyes and/or pigments. At least one of the dichroic dyes according to an embodiment may be an anisotropic absorbent material.

Dichroic dyes may have a major axis with relatively high light transmittance and a minor axis with relatively low light transmittance. As such, the major axis of a dichroic dye may be a light transmission axis and the minor axis of the dichroic dye may be a light absorption axis. In some embodiments, the one or more dichroic dyes included in the color mixing prevention layer DDL may be negative dichroic dyes. The major axis of the one or more dichroic dyes included in the color mixing prevention layer DDL may be parallel (or substantially parallel) to the thickness direction of the first substrate SUB1, e.g., the major axis may be parallel (or substantially parallel) to the third direction DR3. Light transmittance may be relatively high along the thickness direction (e.g., the third direction DR3) of the color mixing prevention layer DDL, and light absorption may be relatively high along a direction parallel (or substantially parallel) to a plane direction (e.g., a direction perpendicular to the thickness direction, such as the first direction DR1, the second direction DR2, etc.) of the color mixing prevention layer DDL.

The color mixing prevention layer DDL according to an embodiment may include at least one of a red dichroic dye, a green dichroic dye, and a blue dichroic dye. The red dichroic dye may transmit red light propagating along the thickness direction of the first substrate SUB1 and absorb red light propagating along a direction inclined with respect to (or transverse to) the thickness direction of the first substrate SUB1. The green dichroic dye may transmit green light propagating along the thickness direction of the first substrate SUB1 and absorb green light propagating along a direction inclined with respect to the thickness direction of the first substrate SUB1. The blue dichroic dye may transmit blue light propagating along the thickness direction of the first substrate SUB1 and absorb blue light emitted along a direction inclined with respect to the thickness direction of the first substrate SUB1.

A type of dichroic dye included in the color mixing prevention layer DDL may vary depending on the light emitted from the light emitting diode ED. In a case that the light emitted from the light emitting diode ED is blue light, the color mixing prevention layer DDL may include a blue dichroic dye. In a case that the light emitted from the light emitting diode ED is a mixture of green light and blue light, the color mixing prevention layer DDL may include a green dichroic dye and a blue dichroic dye. In a case that the light emitted from the light emitting diode ED is a mixture of red light, green light, and blue light, the color mixing prevention layer DDL may include a red dichroic dye, a green dichroic dye, and a blue dichroic dye.

A partition wall BK may be disposed on the color mixing prevention layer DDL.

The partition wall BK may include a first opening OP1, a second opening OP2, and a third opening OP3 that respectively overlap corresponding pixel openings in, for instance, the third direction DR3.

The sizes of the first opening OP1, the second opening OP2, and the third opening OP3 may be different or equivalent. In some implementations, a size of at least two of the first opening OP1, the second opening OP2, and the third opening OP3 may be equivalent.

A first color conversion layer CCL1 may be disposed in the first opening OP1. The first color conversion layer CCL1 may convert supplied (or incident) light into red light. The first color conversion layer CCL1 may include a first quantum dot QD1 and a scatterer SC.

A second color conversion layer CCL2 may be disposed in the second opening OP2.

The second color conversion layer CCL2 may convert supplied light into green light. The second color conversion layer CCL2 may include a second quantum dot QD2 and a scatterer SC.

A transmission layer TL may be disposed in the third opening OP3. The transmission layer TL may be disposed in a portion of the display device corresponding to the blue light emitting area BLA. For instance, the transmission layer TL may be disposed in the space partitioned off by the partition wall BK that overlaps the blue light emitting area BLA in, for example, the third direction DR3.

The transmission layer TL may transmit light incident from the light emitting diode ED. The transmission layer TL may include a scatterer SC. The scatterer SC may be at least one selected from the group consisting of SiO2, BaSO4, Al2O3, ZnO, ZrO2, and TiO2.

Referring to FIG. 5, the display device according to an embodiment may include a first light emitting diode ED1 overlapping the first color conversion layer CCL1 in, for instance, the third direction DR3, and a second light emitting diode ED2 overlapping the second color conversion layer CCL2 in, for example, the third direction DR3.

In a case that light is emitted from the second light emitting diode ED2, the light may be emitted in various directions. Light L1 emitted toward the side (e.g., generally toward the first color conversion layer CCL1 and/or the transmission layer TL) may pass through the encapsulation layer ENC and enter the color mixing prevention layer DDL. As used, herein, the phrase “side light” may refer to “off-axis light” that is incident with the color mixing prevention layer DDL at an oblique angle rather than a perpendicular (or substantially perpendicular) angle. In some implementations, the “side light” may be considered “off-axis light” in relation to the orientation of the major axes of the one or more dichroic dyes DD of the color mixing prevention layer DDL. Thus, the phrases “side light” and “off-axis light” may be used interchangeably. Light incident on (or with) the color mixing prevention layer DDL may be incident in a direction inclined with respect to the major axis of the dichroic dye DD, as shown in FIG. 6.

Referring to FIG. 7, the front transmittance of the color mixing prevention layer DDL is relatively high across an entire (or substantially entire) wavelength band, such as the wavelength band depicted in FIG. 7. However, the lateral transmittance of the color mixing prevention layer DDL may have a significantly lower value (or range of values) in a determined wavelength range. For example, depending on the lateral (or inclined) direction of the light L1, the light L1 may be absorbed without being incident on the first color conversion layer CCL1. Accordingly, unnecessary (or undesired) light conversion due to off-axis light can be prevented (or at least mitigated), and a color reproduction rate can be improved.

In a case that the color mixing prevention layer DDL is omitted, light emitted from the second light emitting diode ED2 toward the first color conversion layer CCL1 may be incident on the first color conversion layer CCL1. Light incident on the first color conversion layer CCL1 may be converted into, for instance, red light by the first quantum dot QD1 and may exit the first color conversion layer CCL1. As such, light may propagate from unintended areas (and/or in unintended directions) and there is a possibility of color mixing, which can reduce display quality of a display device not including the color mixing prevention layer DDL. However, according to various embodiments, the color mixing prevention layer DDL may be utilized to prevent (or at least mitigate) undesired light propagation and color mixing, which can increase display quality of an associated display device.

The quantum dots including the first quantum dot QD1 and the second quantum dot QD2 will be described in more detail below.

In this specification, quantum dots (hereinafter, also referred to as “semiconductor nanocrystals”) include at least one of Group II-VI compounds, Group III-V compounds, Group IV-VI compounds, Group IV elements or compounds, Group I-III-VI compounds, and Group II-III compounds, and in some implementations, may additionally (or alternatively) include at least one of a Group II-III-VI compound and a Group I-II-IV-VI compound. Embodiments, however, are not limited to these examples.

The Group II-VI compounds may be at least one selected from the group consisting of binary compounds (such as CdSe, CdTe, ZnS, ZnSe, ZnTe, ZnO, HgS, HgSe, HgTe, MgSe, MgS, and/or any mixture of two or more of the binary compounds); ternary compounds (such as AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or any mixture of two or more of the ternary compounds); and quaternary compounds (such as HgZnTeS, CdZnSeS, CdZnSeTe, CdZnSTe, CdHgSeS, CdHgSeTe, CdHgSTe, HgZnSeS, HgZnSeTe, HgZnSTe, and/or any mixture of two or more of the quaternary compounds). Embodiments, however, are not limited to these examples.

A Group II-VI compound may further include a Group III metal. Embodiments, however, are not limited to these examples.

The Group III-V compounds may be at least one selected from the group consisting of binary compounds (such as GaN, GaP, GaAs, GaSb, AlN, AlP, AlAs, AlSb, InN, InP, InAs, InSb, and/or any mixture of two or more of the binary compounds); ternary compounds (such as GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and/or any mixture of two or more of the ternary compounds); and quaternary compounds (such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and/or any mixture of two or more of the quaternary compounds). Embodiments, however, are not limited to these examples.

A Group III-V compound may further include a Group II metal (e.g., InZnP). Embodiments, however, are not limited to these examples.

The Group IV-VI compounds may include at least one selected from the group consisting of binary compounds (such as SnS, SnSe, SnTe, PbS, PbSe, PbTe, and/or any mixture of two or more of the binary compounds); ternary compounds (such as SnSeS, SnSeTe, SnSTe, PbSeS, PbSeTe, PbSTe, SnPbS, SnPbSe, SnPbTe, and/or any mixture of two or more of the ternary compounds); and quaternary compounds (such as SnPbSSe, SnPbSeTe, SnPbSTe, and/or any mixture of two or more of the quaternary compounds). Embodiments, however, are not limited to these examples.

The Group IV element or compound may be at least one selected from the group consisting of a mono-element compound (such as Si, Ge, and/or any mixture of two or more of the mono-element compounds), and a binary compound (such as SiC, SiGe, and/or any mixture of two or more of the binary compounds). Embodiments, however, are not limited to these examples.

Examples of the Group I-III-VI compounds include, but are not limited to, at least one of CuInSe2, CuInS2, CuInGaSe, and CuInGaS.

Examples of the Group I-II-IV-VI compounds include, but are not limited to, at least one ofCuZnSnSe and CuZnSnS.

The Group IV element or compound may be at least one selected from the group consisting of a single element (such as Si, Ge, and/or any mixture of two or more of the single elements); and binary compounds (such as SiC, SiGe, and/or any mixture of two or more of the binary compounds). Embodiments, however, are not limited to these examples.

The Group II-III-VI compounds may include at least one of ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, and HgAlTe. In some embodiments, the Group II-III-VI compounds may be at least one selected from the group consisting of HgInTe, MgGaS, MgAlS, MgInS, MgGaSe, MgAlSe, and MgInSe. Embodiments, however, are not limited to these examples.

The Group I-II-IV-VI compounds may be at least one of CuZnSnSe and CuZnSnS. Embodiments, however, are not limited to these examples.

In an embodiment, the quantum dots may not include cadmium.

Quantum dots may include semiconductor nanocrystals based on Group III-V compounds including, for example, indium and phosphorus.

The Group III-V compound may further include zinc.

Quantum dots may include semiconductor nanocrystals based on Group II-VI compounds including, for instance, chalcogen elements (e.g., sulfur, selenium, tellurium, and/or any combination of the chalcogen elements) and zinc.

In quantum dots, the above-mentioned binary compounds, ternary compounds, and/or quaternary compounds may exist in a quantum dot at a uniform concentration, or may exist in the quantum dot with a concentration distribution partially divided into different states.

In some embodiments, one quantum dot may have a core-shell structure surrounding at least one other quantum dot.

The interface between the core and the shell may have a concentration gradient in which the concentration of elements present in the shell decreases toward the center.

In some embodiments, quantum dots may have a core-shell structure including a core containing at least one of the above-described semiconductor nanocrystals and a shell surrounding the core.

The shell of a quantum dot may serve as a protective layer to maintain semiconductor properties by preventing (or at least mitigating) chemical denaturation of the core and/or as a charging layer to impart electrophoretic properties to the quantum dot.

The shell may be a single-layer or multi-layered structure.

The interface between the core and the shell may have a concentration gradient in which the concentration of elements present in the interface decreases toward the center.

Examples of a shell of a quantum dot include at least one of metal oxides, non-metal oxides, and semiconductor compounds.

For example, the oxide of the metal or non-metal may be a binary compound (such as SiO₂, Al₂O₃, TiO₂, ZnO, MnO, Mn₂O₃, Mn₃O₄, CuO, FeO, Fe₂O₃, Fe₃O₄, CoO, CO₃O₄, NiO, MgAl₂O₄, CoFe₂O₄, NiFe₂O₄, CoMn₂O₄, etc.), but embodiments are not limited to these examples.

The semiconductor compounds may include, for instance, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., however, embodiments are not limited to these examples.

The interface between the core and the shell may have a concentration gradient in which the concentration of elements present in the at least one of the shell and the interface decreases toward the center, e.g., toward the core and/or a center of the core.

In some embodiments, the semiconductor nanocrystal may have a structure including a single semiconductor nanocrystal core and a multi-layered shell surrounding the single semiconductor nanocrystal core.

In an embodiment, the multilayer shell may have two or more layers, such as 2, 3, 4, 5, or more layers.

Two adjacent layers of the multilayer shell may have a single composition (or share a same composition) or different compositions.

In the multilayer shell, each layer may have a composition that changes along a radius of the quantum dot (or layer of the quantum dot).

Quantum dots may have a full width at half maximum (“FWHM”) of the emission wavelength spectrum of about 45 nm or less, such as about 40 nm or less, for instance, about 30 nm or less, and in this range, color purity or color reproducibility can be improved.

According to some embodiments, since light emitted through (or via) these quantum dots may be emitted in all (or substantially all) directions, an optical viewing angle of a display device including the quantum dots can be improved.

One or more of the quantum dots may have different energy band gaps between the shell material and the core material.

For example, the energy band gap of the shell material may be larger than the energy band gap of the core material.

In some embodiments, the energy band gap of the shell material may be smaller than the energy band gap of the core material.

The quantum dots may have a multi-layered shell.

In a multilayer shell, the energy band gap of an outer layer (e.g., a layer further from the core of the associated quantum dot) may be larger than the energy band gap of an inner layer (e.g., a layer closer to the core of the associated quantum dot).

In a multilayer shell, the energy band gap of an outer layer may be smaller than the energy band gap of an inner layer.

In some embodiments, the quantum dots may be utilized to control absorption and/or emission wavelengths by adjusting a composition and/or size of the quantum dots.

The maximum emission peak wavelength of a quantum dot may be in a range of, for instance, a wavelength (or range of wavelengths) associated with ultraviolet radiation to a wavelength (or range of wavelengths associated with infrared radiation, or even longer wavelength(s) than infrared radiation. For instance, the range of the maximum emission peak wavelength of a quantum dot may have a lower bound in a range of about 10 nm to about 400 nm and an upper bound in a range of about 780 nm to about 1 mm or even longer. Embodiments, however, are not limited to these examples.

In some embodiments, the quantum dots may have quantum efficiency of at least about 10%, such as at least about 30%, for instance at least about 50%, e.g., at least about 60%, for example at least about 70%, e.g., at least about 90%, or even at least about 100%.

Quantum dots may, in some embodiments, have a relatively narrow spectrum. The quantum dots may have a FWHM of the emission wavelength spectrum of, for example, about 50 nm or less, such as about 45 nm or less, for instance about 40 nm or less, e.g., about 30 nm or less.

The quantum dots may have a particle size in a range of about 1 nm or more to about 100 nm or less. The size of a particle refers to the diameter of the particle or the diameter determined by assuming a spherical shape based on a two-dimensional image obtained by, for instance, transmission electron microscopy analysis.

In some embodiments, the size of the quantum dots may be in a range of about 1 nm to about 20 nm. For instance, the lower end of the range may be at least about 2 nm, e.g., at least about 3 nm, for instance at least about 4 nm, and the upper end of the range may be at most about 50 nm, e.g., at most about 40 nm, such as at most about 30 nm, for instance at most about 20 nm, for example at most about 15 nm, such as at least about 10 nm. In some implementations, the size may be several nanometers or less.

The shape of the quantum dot is not particularly limited. For example, the shape of the quantum dot may include, but is not limited to, a sphere, polyhedron, pyramid, multi-pod (e.g., bipod, tripod, quadpod, etc.), square, cuboid, nanotube, nanorod, nanowire, nanosheet, or any combination of these shapes. Embodiments, however, are not limited to these example shapes.

Quantum dots are commercially available or can be synthesized.

The particle size of a quantum dot can be controlled relatively freely during colloid synthesis, and the particle size can also be adjusted uniformly or even made to be uniform (or substantially uniform).

Quantum dots may include organic ligands (e.g., having hydrophobic and/or hydrophilic moieties).

The organic ligand residue may be bound to a surface of the quantum dot.

The organic ligand may include at least one of RCOOH, RNH₂, R₂NH, R₃N, RSH, R₃PO, R₃P, ROH, RCOOR, RPO(OH)₂, RHPOOH, and R₂POOH, where each R is independently at least one of a substituted or unsubstituted alkyl of C3 to C40 (e.g., C5 or more and C24 or less), a substituted or unsubstituted alkenyl, a substituted or unsubstituted aliphatic hydrocarbon group of C3 to C40, a substituted or unsubstituted aryl group of C6 to C40, and a substituted or unsubstituted aromatic hydrocarbon group of C6 to C40 (e.g., C6 or more and C20 or less). Embodiments, however, are not limited to these examples.

Examples of the organic ligand may include at least one of thiol compounds (such as methane thiol, ethane thiol, propane thiol, butane thiol, pentane thiol, hexane thiol, octane thiol, dodecane thiol, hexadecane thiol, octadecane thiol, and benzyl thiol), methane amine, ethane amine, propane amine, butane amine, pentyl amine, hexyl amine, octyl amine, nonyl amine, decyl amine, dodecyl amine, hexadecyl amine, octadecyl amine, dimethyl amine, diethyl amine, dipropyl amine, amines (such as tributylamine, trioctylamine, etc.), carboxylic acid compounds (such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, and benzoic acid), phosphine compounds (such as methyl phosphine, ethyl phosphine, propyl phosphine, butyl phosphine, pentyl phosphine, octyl phosphine, dioctyl phosphine, tributyl phosphine, trioctyl phosphine, etc.), phosphines (such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, and trioctyl phosphine oxide compounds or their oxide compounds), diphenyl phosphine, triphenyl phosphine compounds or their oxide compounds, C5 to C20 alkyl phosphinic acids, and C5 to C20 alkyl phosphonic acids (such as hexylphosphinic acid, octylphosphinic acid, dodecanephosphinic acid, tetradecanephosphinic acid, hexadecanephosphinic acid, and octadecanephosphinic acid). Embodiments, however, are not limited to these examples.

Quantum dots may include hydrophobic organic ligands alone or in a mixture of one or more types.

The hydrophobic organic ligand may not contain a photopolymerizable residue (e.g., an acrylate group, a methacrylate group, etc.).

Referring again to FIG. 4, the color conversion portion CC includes a second substrate SUB2 overlapping the first substrate SUB1 in, for instance, the third direction DR3.

The second substrate SUB2 may include a flexible material, such as plastic that can be intentionally bent, folded, rolled, twisted, and/or otherwise flexed, as opposed to a conventional rigid substrate. In some embodiments, the second substrate SUB2 may include at least one flexible area and at least one rigid area. In an embodiment, the second substrate SUB2 may be a rigid substrate.

The color conversion portion CC may include a first color filter CF1, a second color filter CF2, and a third color filter CF3 disposed between the second substrate SUB2 and the display portion DC.

The first color filter CF1 may overlap the transmission layer TL in, for example, the third direction DR3.

The first color filter CF1 can transmit blue light that has passed through the transmission layer TL and absorb light of the remaining (or other) wavelengths, thereby increasing the purity of blue light emitted to the outside of the display device.

The second color filter CF2 may overlap the first color conversion layer CCL1 in, for example, the third direction DR3.

The second color filter CF2 can transmit red light that has passed through the first color conversion layer CCL1 and absorb light of the remaining (or other) wavelengths, thereby increasing the purity of red light emitted to the outside of the display device.

The third color filter CF3 may overlap the second color conversion layer CCL2 in, for example, the third direction DR3.

The third color filter CF3 can transmit green light that has passed through the second color conversion layer CCL2 and absorb light of the remaining (or other) wavelengths, thereby increasing the purity of green light emitted to the outside of the display device.

At least two among the third color filter CF3, the second color filter CF2, and the first color filter CF1 may overlap one another in the non-light emitting area NLA in, for example, the third direction DR3, and as such, may serve as a light blocking layer.

The non-light emitting area NLA may overlap both the pixel defining layer PDL of the display portion DC and the partition wall BK of the color conversion portion CC in, for example, the third direction DR3.

A third insulating layer IL3 may be disposed between the first to third color filters CF1, CF2, and CF3 and the display portion DC.

The third insulating layer IL3 may include an organic material and/or an inorganic material, such as a silicon nitride (SiNx), silicon dioxide (SiO₂), a silicon oxynitride, etc.

A filling layer FL may be positioned between the third insulating layer IL3 and the display portion DC in, for example, the third direction DR3.

The filling layer FL may bond components formed on the first substrate SUB1 and components formed on the second substrate SUB2.

The first substrate SUB1 and the second substrate SUB2 may be combined (or coupled) together by the filling layer FL.

The display device according to an embodiment may include a color mixing prevention layer (e.g., color mixing prevention layer DDL), thereby preventing (or at least mitigating) color mixing due to off-axis light emitted from, for instance, a light emitting diode ED. This may improve the color gamut of an associated display device, and thereby, provide a display device with improved display quality.

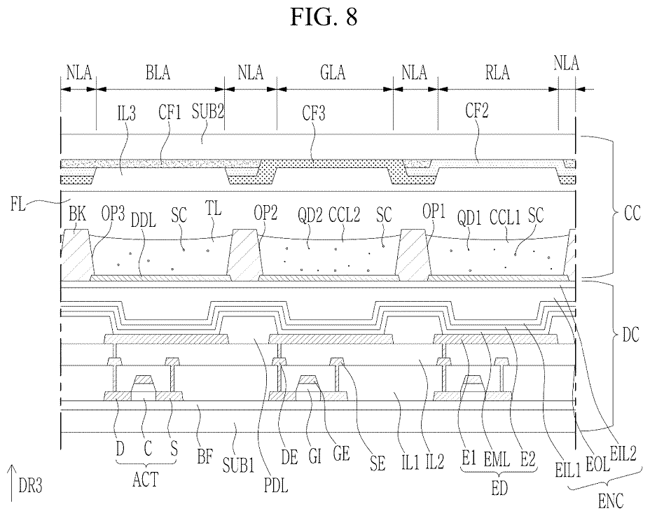

Hereinafter, various display panels according to some embodiments will be described with reference to FIGS. 8 to 15.

FIGS. 8, 9, 10, 11, 12, 13, 14, and 15 are schematic cross-sectional views of various display panels according to some embodiments.

Descriptions of components that are the same as those described above will be omitted or briefly described.

First, referring to FIG. 8, the color conversion portion CC according to an embodiment may include a color mixing prevention layer DDL disposed on the encapsulation layer ENC.

The color mixing prevention layer DDL may overlap a portion of the first substrate SUB1 in, for example, the third direction DR3.

The color mixing prevention layer DDL may overlap the openings (e.g., first to third openings OP1, OP2, and OP3) included in the partition wall BK in, for example, the third direction DR3.

The color mixing prevention layer DDL may be patterned.

The color mixing prevention layer DDL may be spaced apart from at least a portion of the partition wall BK.

The color mixing prevention layer DDL may not overlap at least a portion of the partition wall BK in, for example, the third direction DR3. In some implementations, portions of the color mixing prevention layer DDL may overlap corresponding portions of the partition wall BK in, for instance, the third direction DR3. As such, the portions of the color mixing prevention layer DDL may be disposed between the corresponding portions of the partition wall BK and the encapsulation layer ENC in, for example, the third direction DR3.

The color mixing prevention layer DDL may overlap at least one of the first color conversion layer CCL1, the second color conversion layer CCL2, and the transmission layer TL in, for example, the third direction DR3.

The color mixing prevention layer DDL can prevent (or at least mitigate) color mixing by absorbing off-axis light that might otherwise be made incident on (or with) the first color conversion layer CCL1, the second color conversion layer CCL2, and/or the transmission layer TL.

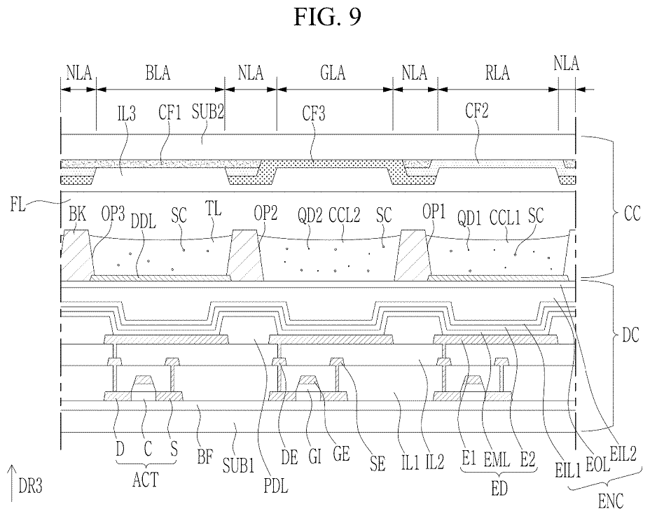

Referring to FIG. 9, the color mixing prevention layer DDL according to an embodiment may overlap at least a portion of the first substrate SUB1 in, for example, the third direction DR3.

The color mixing prevention layer DDL may overlap at least one of the first color conversion layer CCL1, the second color conversion layer CCL2, and the transmission layer TL in, for example, the third direction DR3.

The color mixing prevention layer DDL may be spaced apart from at least one of the first color conversion layer CCL1, the second color conversion layer CCL2, and the transmission layer TL.

The color mixing prevention layer DDL may be formed only in areas where color mixing can occur.

Although FIG. 9 depicts an embodiment in which the color mixing prevention layer DDL is disposed in the blue light emitting area BLA and the red light emitting area RLA, and is not disposed in the green light emitting area GLA, embodiments are not limited to this example.

For instance, in some embodiments, the color mixing prevention layer DDL may be selectively disposed in at least one of the red light emitting area RLA, the green light emitting area GLA, and the blue light emitting area BLA, and selectively not disposed in at least one remaining light emitting area among the red light emitting area RLA, the green light emitting area GLA, and the blue light emitting area BLA.

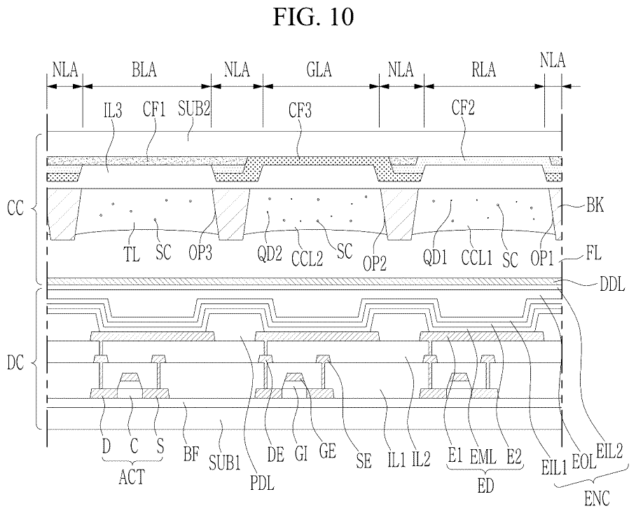

Referring to FIG. 10, the stacked structure of the display portion DC may be similar to the stacked structure described in association with FIG. 4.

The color conversion portion CC may include a second substrate SUB2 that may overlap the first substrate SUB1 in, for example, the third direction DR3.

The second substrate SUB2 may include a flexible material, such as plastic, that can be intentionally bent, folded, rolled, twisted, and/or otherwise flexed, as opposed to a conventional rigid substrate. In some embodiments, the second substrate SUB2 may include at least one flexible area and at least one rigid area. In an embodiment, the second substrate SUB2 may be a rigid substrate.

The color conversion portion CC includes a first color filter CF1, a second color filter CF2, and a third color filter CF3 disposed between the second substrate SUB2 and the display portion DC.

At least two among the third color filter CF3, the second color filter CF2, and the first color filter CF1 may overlap one another in the non-light emitting area NLA in, for example, the third direction DR3, and as such, may serve as a light blocking layer.

The non-light emitting area NLA may overlap both the pixel defining layer PDL of the display portion DC and the partition wall BK of the color conversion portion CC in, for example, the third direction DR3.

A third insulating layer IL3 may be disposed between the first to third color filters CF1, CF2, and CF3 and the display portion DC in, for instance, the third direction DR3.

The third insulating layer IL3 may include at least one of an organic material and an inorganic material, such as a silicon nitride (SiNx), silicon dioxide (SiO₂), silicon oxynitride, etc.

A partition wall BK, a first color conversion layer CCL1, a second color conversion layer CCL2, and a transmission layer TL may be positioned between the third insulating layer IL3 and the display portion DC in, for example, the third direction DR3.

The partition wall BK may be disposed on a side (e.g., a lower side) of the third insulating layer IL3.

The partition wall BK may include a first opening OP1, a second opening OP2, and a third opening OP3 that overlap the pixel opening in, for example, the third direction DR3.

The first color conversion layer CCL1, the second color conversion layer CCL2, and the transmission layer TL may be disposed on a side (e.g., a lower side) of the third insulating layer IL3.

The first color conversion layer CCL1 may be disposed in the first opening OP1.

The second color conversion layer CCL2 may be disposed in the second opening OP2.

The transmission layer TL may be disposed in the third opening OP3.

A filling layer FL may be disposed between the display portion DC and each of the partition wall BK, the first color conversion layer CCL1, the second color conversion layer CCL2, and the transmission layer TL in, for instance, the third direction DR3.

The filling layer FL may bond components formed on the first substrate SUB1 and components formed on the second substrate SUB2.

The first substrate SUB1 and the second substrate SUB2 may be combined (or coupled) by the filling layer FL.

A color mixing prevention layer DDL may be disposed between the filling layer FL and the display portion DC in, for instance, the third direction DR3.

The color conversion portion CC may include the color mixing prevention layer DDL disposed on the encapsulation layer ENC.

The color mixing prevention layer DDL may overlap an entire (or substantially entire) surface of the first substrate SUB1 in, for example, the third direction DR3.

The color mixing prevention layer DDL according to an embodiment may include one or more (e.g., multiple) dichroic dyes and/or pigments.

At least one of the dichroic dyes according to an embodiment may be an anisotropic absorbent material.

Dichroic dyes may have a major axis with relatively high light transmittance and a minor axis with relatively low light transmittance.

The major axes of the one or more dichroic dyes included in the color mixing prevention layer DDL may be parallel (or substantially parallel) to the thickness direction of the first substrate SUB1, e.g., the major axis may be parallel (or substantially parallel) to the third direction DR3. Light transmittance may be relatively high along the thickness direction (e.g., the third direction DR3) of the color mixing prevention layer DDL, and light absorption may be relatively high along a direction parallel (or substantially parallel) to a plane direction (e.g., a direction perpendicular to the thickness direction, such as the first direction DR1, the second direction DR2, etc.) of the color mixing prevention layer DDL.

The color mixing prevention layer DDL according to an embodiment may include at least one of a red dichroic dye, a green dichroic dye, and a blue dichroic dye.

The red dichroic dye may transmit red light propagating along the thickness direction of the first substrate SUB1 and absorb red light propagating along a direction inclined with respect to the thickness direction of the first substrate SUB1.

The green dichroic dye may transmit green light propagating along the thickness direction of the first substrate SUB1 and absorb green light propagating along a direction inclined with respect to the thickness direction of the first substrate SUB1.

The blue dichroic dye may transmit blue light propagating along the thickness direction of the first substrate SUB1 and absorb blue light propagating along a direction inclined with respect to the thickness direction of the substrate SUB1.

A type of dichroic dye included in the color mixing prevention layer DDL may vary depending on the light emitted from the light emitting diode ED.

In a case that the light emitted from the light emitting diode ED is blue light, the color mixing prevention layer DDL may include a blue dichroic dye.

In a case that the light emitted from the light emitting diode ED is a mixture of green light and blue light, the color mixing prevention layer DDL may include a green dichroic dye and a blue dichroic dye.

In a case that the light emitted from the light emitting diode ED is a mixture of red light, green light, and blue light, the color mixing prevention layer DDL may include a red dichroic dye, a green dichroic dye, and a blue dichroic dye.

The color mixing prevention layer DDL according to an embodiment may prevent (or at least mitigate) color mixing caused, at least in part, by light emitted from, for instance, a light emitting diode ED in a direction oblique to the orientation of the major axes of the one or more dichroic dyes DD, thereby providing a display device with improved color reproduction and display quality.

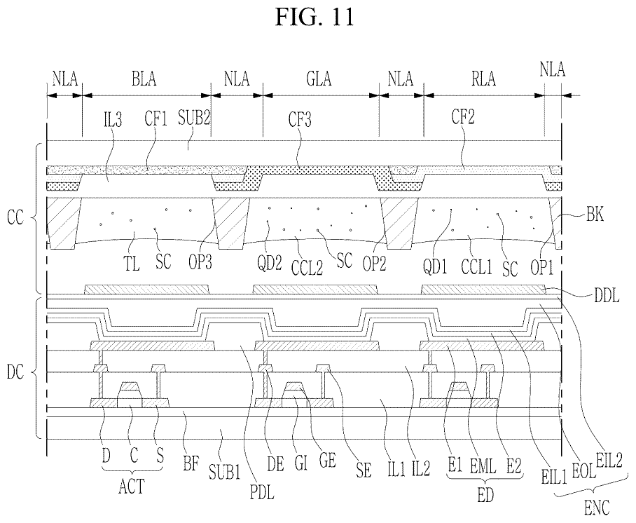

Referring to FIG. 11, the color conversion portion CC according to an embodiment may include a color mixing prevention layer DDL disposed on the encapsulation layer ENC.

The color mixing prevention layer DDL may overlap a portion of the first substrate SUB1 in, for example, the third direction DR3.

The color mixing prevention layer DDL may overlap the openings (e.g., the first to third openings OP1, OP2, and OP3) included in the partition wall BK in, for example, the third direction DR3.

The color mixing prevention layer DDL may overlap the pixel opening included in the pixel defining layer PDL in, for example, the third direction DR3.

The color mixing prevention layer DDL may be spaced apart from at least a portion of the partition wall BK.

The color mixing prevention layer DDL may not overlap at least a portion of the partition wall BK in, for example, the third direction DR3.

The color mixing prevention layer DDL may not overlap at least a portion of the pixel defining layer PDL in, for example, the third direction DR3. In some implementations, the portions of the color mixing prevention layer DDL may overlap corresponding portions of the pixel defining layer PDL in, for example, the third direction DR3.

The color mixing prevention layer DDL may overlap the first color conversion layer CCL1, the second color conversion layer CCL2, and the transmission layer TL in, for example, the third direction DR3.

The color mixing prevention layer DDL can prevent (or at least mitigate) color mixing by absorbing off-axis light that might otherwise be made incident on (or with) the first color conversion layer CCL1, the second color conversion layer CCL2, and/or the transmission layer TL.

The color mixing prevention layer DDL according to an embodiment may be disposed between the filling layer FL and the encapsulation layer ENC.

The color mixing prevention layer DDL may be disposed above (e.g., directly above) the encapsulation layer ENC, and may contact (e.g., directly contact) the filling layer FL, but the arrangement of the color mixing prevention layer DDL is not limited to this example.

A separate protective layer may be positioned between the color mixing prevention layer DDL and the filling layer FL.

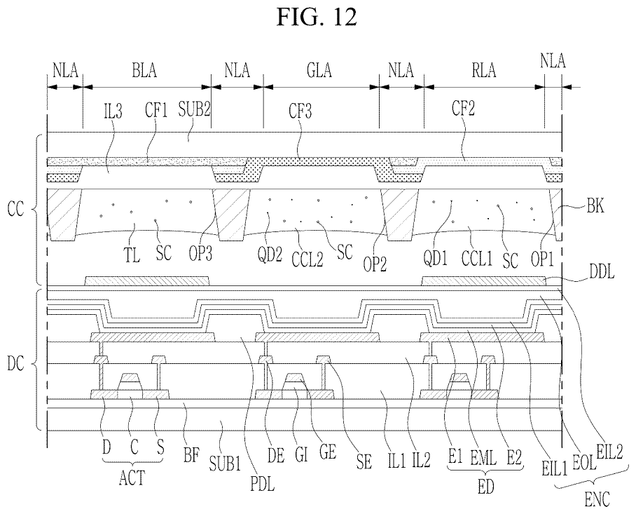

Referring to FIG. 12, the color mixing prevention layer DDL according to an embodiment may overlap at least a portion of the first substrate SUB1 in, for example, the third direction DR3.

The color mixing prevention layer DDL may overlap at least a portion of the encapsulation layer ENC in, for example, the third direction DR3.

The color mixing prevention layer DDL may overlap at least one of the first color conversion layer CCL1, the second color conversion layer CCL2, and the transmission layer TL in, for example, the third direction DR3.

The color mixing prevention layer DDL may be spaced apart from at least one of the first color conversion layer CCL1, the second color conversion layer CCL2, and the transmission layer TL.

The color mixing prevention layer DDL may be formed only in areas where color mixing can occur.

Although FIG. 12 depicts an embodiment in which the color mixing prevention layer DDL is disposed in the blue light emitting area BLA and the red light emitting area RLA, and is not disposed in the green light emitting area GLA, embodiments are not limited to this example.

For instance, in some implementations, the color mixing prevention layer DDL may be selectively disposed in at least one of the red light emitting area RLA, the green light emitting area GLA, and the blue light emitting area BLA, and selectively not disposed in at least one remaining light emitting area among the red light emitting area RLA, the green light emitting area GLA, and the blue light emitting area BLA.

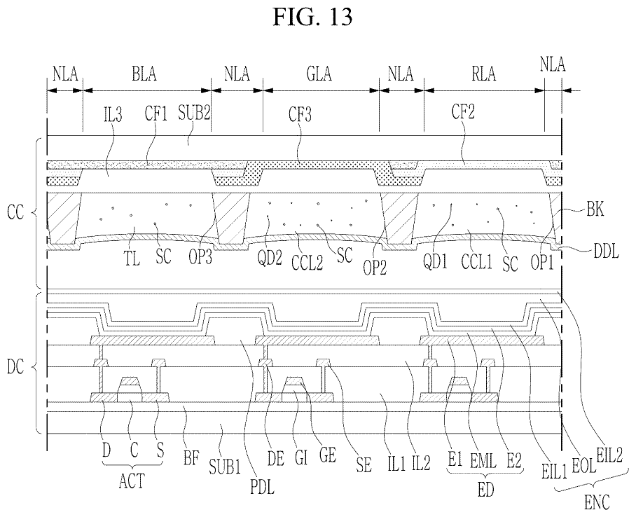

Referring to FIG. 13, the color mixing prevention layer DDL according to an embodiment may be disposed (in, for instance, the third direction DR3) between the partition wall BK and the filling layer FL, between the first color conversion layer CCL1 and the filling layer FL, between the second color conversion layer CCL2 and the filling layer FL, and between the transmission layer TL and the filling layer FL.

The color mixing prevention layer DDL may otherwise have the same structure as described in association with FIG. 10, except for the position where the color mixing prevention layer DDL is disposed.

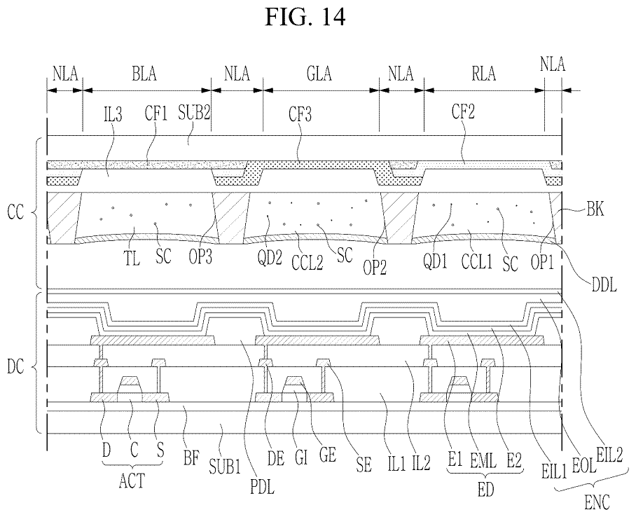

Referring to FIG. 14, the color mixing prevention layer DDL according to an embodiment may be disposed (in, for example, the third direction DR3) between the first color conversion layer CCL1 and the filling layer FL, between the second color conversion layer CCL2 and the filling layer FL, and between the transmission layer TL and the filling layer FL.

The color mixing prevention layer DDL may be disposed between adjacent partition walls BK, such as in a view in the third direction DR3.

The color mixing prevention layer DDL may overlap the first to third openings OP1, OP2, and OP3 included in the partition wall BK in, for example, the third direction DR3.

The color mixing prevention layer DDL may overlap the pixel opening included in the pixel defining layer PDL in, for example, the third direction DR3.

The color mixing prevention layer DDL may be spaced apart from the partition wall BK in a view in, for instance, the third direction DR3. In some implementations, the color mixing prevention layer DDL may contact (e.g., directly contact) one or more portions of the partition wall BK.

The color mixing prevention layer DDL may overlap the first color conversion layer CCL1, the second color conversion layer CCL2, and the transmission layer TL in, for example, the third direction DR3.

The color mixing prevention layer DDL may contact (e.g., directly contact) the first color conversion layer CCL1, the second color conversion layer CCL2, and the transmission layer TL.

The color mixing prevention layer DDL can prevent (or at least mitigate) color mixing by absorbing off-axis light that might otherwise be made incident on (or with) the first color conversion layer CCL1, the second color conversion layer CCL2, and/or the transmission layer TL.

Depending on the embodiment, a separate protective layer may be positioned between the color mixing prevention layer DDL, the first color conversion layer CCL1, the second color conversion layer CCL2, and the transmission layer TL.

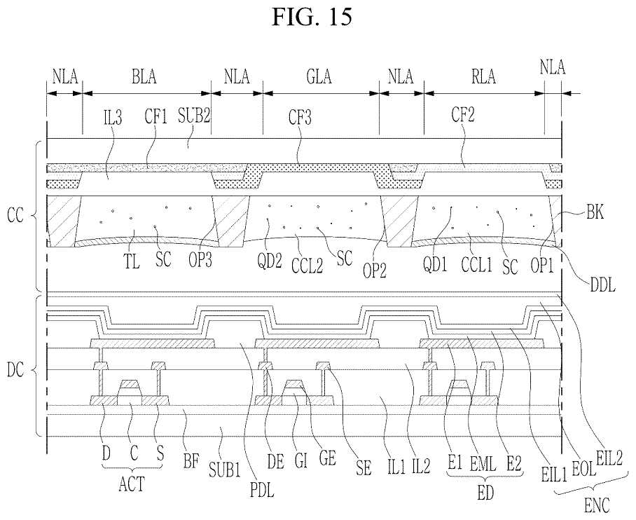

Referring to FIG. 15, the color mixing prevention layer DDL may overlap at least one of the first color conversion layer CCL1, the second color conversion layer CCL2, and the transmission layer TL in, for example, the third direction DR3.

The color mixing prevention layer DDL may be spaced apart from at least one of the first color conversion layer CCL1, the second color conversion layer CCL2, and the transmission layer TL.

The color mixing prevention layer DDL may be formed only in areas where color mixing can occur.

Although FIG. 15 depicts an embodiment in which the color mixing prevention layer DDL is disposed in the blue light emitting area BLA and the red light emitting area RLA, and is not disposed in the green light emitting area GLA, embodiments are not limited to this example.

For instance, in some implementations, the color mixing prevention layer DDL may be selectively disposed in at least one of the red light emitting area RLA, the green light emitting area GLA, and the blue light emitting area BLA, and selectively not disposed in at least one remaining light emitting area among the red light emitting area RLA, the green light emitting area GLA, and the blue light emitting area BLA.

A display device according to one or more embodiments can prevent (or at least mitigate) unnecessary (or undesired) light conversion due to light emitted from a light emitting diode in a lateral (or sufficiently inclined) direction, and thereby, provide an improved color gamut and increased display quality.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatuses of the disclosed embodiments. Accordingly, embodiments are to be considered illustrative and not as restrictive, and embodiments are not to be limited to the details given herein.

What is claimed is:

1. A display device comprising:
a first substrate;
a transistor disposed on a surface of the first substrate;
a light emitting diode electrically connected to the transistor;
an encapsulation layer disposed on the light emitting diode;
a color mixing prevention layer disposed on the encapsulation layer;
a partition wall disposed on the color mixing prevention layer, the partition wall including a first opening, a second opening, and a third opening;
a first color conversion layer disposed in the first opening;
a second color conversion layer disposed in the second opening; and
a transmission layer disposed in the third opening,
wherein the color mixing prevention layer includes one or more dichroic dyes.

2. The display device of claim 1, wherein
the one or more dichroic dyes have a major axis along which light is transmitted and a minor axis along which light is absorbed, and
the major axis extends in a first direction perpendicular to the surface.

3. The display device of claim 2, wherein
the minor axis extends in a second direction perpendicular to the first direction.

4. The display device of claim 2, wherein
the one or more dichroic dyes include at least one of a red dichroic dye, a green dichroic dye, and a blue dichroic dye.

5. The display device of claim 1, wherein
the color mixing prevention layer is configured to absorb light having an oblique angle of incidence with the color mixing prevention layer.

6. The display device of claim 1, wherein
the partition wall, the first color conversion layer, the second color conversion layer, and the transmission layer have respective first surfaces facing the first substrate, and
the respective first surfaces of the partition wall, the first color conversion layer, the second color conversion layer, and the transmission layer directly contact the color mixing prevention layer.

7. The display device of claim 1, wherein
in a view in a direction perpendicular to the surface, the color mixing prevention layer respectively overlaps each of the first opening, the second opening, and the third opening, and does not overlap at least a portion of the partition wall.

8. The display device of claim 1, wherein
in a view in a direction perpendicular to the surface, the color mixing prevention layer overlaps at least one of the first color conversion layer, the second color conversion layer, and the transmission layer.

9. The display device of claim 8, wherein
in the view, the color mixing prevention layer is spaced apart from at least one of the first color conversion layer, the second color conversion layer, and the transmission layer.

10. A display device, comprising:
a first substrate;
a transistor disposed on a surface of the first substrate;
a light emitting diode electrically connected to the transistor;
an encapsulation layer disposed on the light emitting diode;
a color mixing prevention layer disposed on the encapsulation layer;
a second substrate overlapping the first substrate in a direction perpendicular to the surface;
a partition wall disposed on the second substrate, the partition wall including a first opening, a second opening, and a third opening; and
a first color conversion layer disposed in the first opening;
a second color conversion layer disposed in the second opening; and
a transmission layer disposed in the third opening,
wherein the color mixing prevention layer includes one or more dichroic dyes.

11. The display device of claim 10, further comprising:
a filling layer disposed between the partition wall and the encapsulation layer in the direction.

12. The display device of claim 11, wherein
the color mixing prevention layer is disposed between the filling layer and the encapsulation layer in the direction.

13. The display device of claim 12, wherein
the color mixing prevention layer overlaps an entirety of the surface in the direction.

14. The display device of claim 12, wherein
the color mixing prevention layer respectively overlaps each of the first color conversion layer, the second color conversion layer, and the transmission layer in a view in the direction.

15. The display device of claim 14, wherein
the color mixing prevention layer does not overlap at least a portion of the partition wall in the view.

16. The display device of claim 12, wherein
the color mixing prevention layer overlaps at least one of the first color conversion layer, the second color conversion layer, and the transmission layer in a view in the direction.

17. The display device of claim 16, wherein
the color mixing prevention layer does not overlap at least one of the first color conversion layer, the second color conversion layer, and the transmission layer in the view.

18. The display device of claim 11, wherein
the color mixing prevention layer is disposed between the filling layer and the partition wall in the direction.

19. The display device of claim 18, wherein
the color mixing prevention layer respectively overlaps each of the first opening, the second opening, and the third opening in a view in the direction, and
in the view, the color mixing prevention layer is spaced apart from at least a portion of a surface of the partition wall.

20. The display device of claim 18, wherein
the color mixing prevention layer does not overlap at least one of the first color conversion layer, the second color conversion layer, and the transmission layer in a view in the direction.
